(19) United States
(12) Patent Application Publication
(10) Pub. No.: US 2025/0329592 A1
(43) Pub. Date: Oct. 23, 2025

(54) SEMICONDUCTOR DEVICE AND METHOD FOR MANUFACTURING SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Naoya NISHIJIMA, Ibo Hyogo (JP); Koji ONISHI, Ibo Hyogo (JP); Toru SHONO, Himeji Hyogo (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/829,348

(22) Filed: Sep. 10, 2024

(30) Foreign Application Priority Data
Apr. 23, 2024 (JP) 2024-070039

(51) Int. Cl. H01L 23/13; H01L 21/48; H01L 23/00

(52) U.S. Cl. CPC H01L 23/13; H01L 21/4803; H01L 24/26; H01L 24/32; H01L 24/83; H01L 24/29; H01L 2224/26175; H01L 2224/29139; H01L 2224/32225; H01L 2224/83201; H01L 2924/13055

(57) ABSTRACT

A semiconductor device 100 includes: a substrate; a mounting material disposed on the substrate; and a semiconductor element disposed on the mounting material. A wall-shaped wall and a non-wall region in which the wall is not provided are formed along a perimeter of the mounting material on the substrate.

### CROSS-REFERENCE TO RELATED APPLICATIONS

This application is based upon and claims the benefit of priority from Japanese Patent Application No. 2024-070039, filed on Apr. 23, 2024; the entire contents of which are incorporated herein by reference.

### FIELD

Embodiments relate to a semiconductor device and a method for manufacturing a semiconductor device.

### BACKGROUND

A technique for connecting a semiconductor element and a metal substrate by using a mounting material in, for example, an LGA (Land Grid Array) semiconductor device having a drain common structure has been developed.

### BRIEF DESCRIPTION OF THE DRAWINGS

FIG. 1A is a perspective view of a semiconductor device according to an embodiment;

FIG. 1B is a perspective view of a substrate of the semiconductor device;

FIG. 2 is an enlarged cross-sectional view taken along line II-II in FIG. 1A;

FIG. 3 is a flowchart illustrating a method for manufacturing the semiconductor device;

FIG. 4A is a perspective view of the substrate in a substrate processing process;

FIG. 4B is a perspective view of the substrate in the substrate processing process;

FIG. 5A is a perspective view of the substrate in a mounting material disposition process;

FIG. 5B is a perspective view of the semiconductor device in a semiconductor element disposition process;

FIG. 6A is a perspective view of a semiconductor device according to a modification; and

FIG. 6B is a perspective view of a substrate of the semiconductor device according to the modification.

### DETAILED DESCRIPTION

A semiconductor device according to an embodiment includes: a substrate; a mounting material disposed on the substrate; and a semiconductor element disposed on the mounting material. A wall-shaped barrier part and a non-barrier region in which the barrier part is not provided are formed along a perimeter of the mounting material on the substrate.

Hereinafter, embodiments of the invention will be described with reference to the drawings. The embodiments are not intended to limit the invention. The drawings are schematic or conceptual and, for example, the proportions of respective parts are not necessarily the same as the actual proportions. In the specification and drawings, components similar to those described in regard to a drawing thereinabove are marked with like reference numerals, and a detailed description is omitted as appropriate.

Terms and the like, such as “parallel” and “same”, used in the specification to specify shapes or geometrical conditions and the degrees thereof are not limited to their strict meanings and are construed as including the extent to which similar functions can be expected.

### 1. EMBODIMENT

### 1.1. Semiconductor Device 100

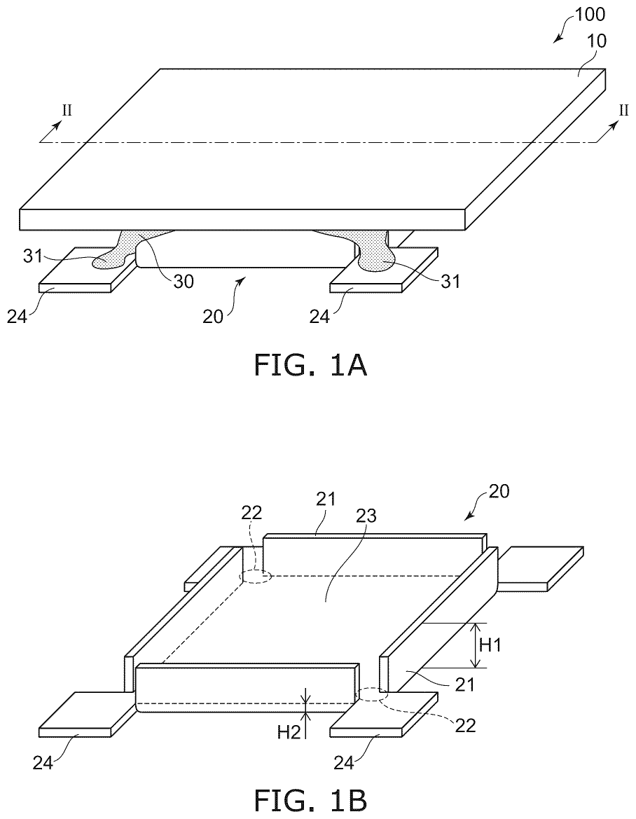

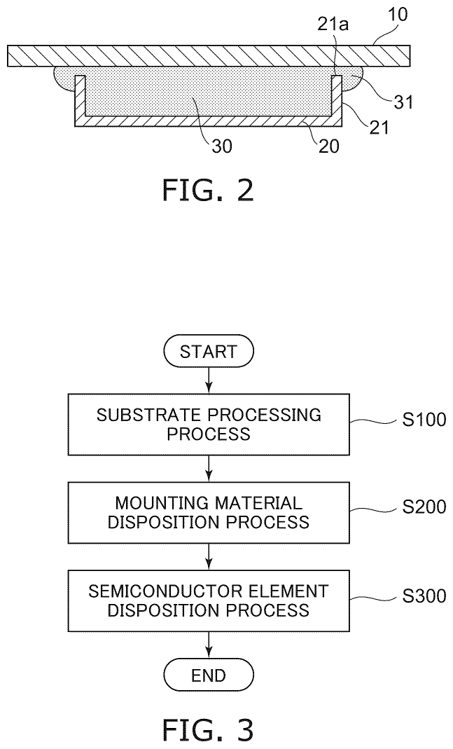

A semiconductor device 100 according to this embodiment will be described with reference to FIG. 1A to FIG. 2. As shown in FIG. 1A, the semiconductor device 100 includes a substrate 20, a mounting material 30 disposed on the substrate 20, and a semiconductor element (semiconductor chip) 10 disposed on the mounting material 30.

The semiconductor element 10 has a rectangular shape in plan view and is, for example, an IGBT. Note that the semiconductor element 10 is not limited to a specific type and may be, for example, a MOSFET or an FRD.

FIG. 1B is a perspective view of the substrate 20. As shown in FIG. 1B, the substrate 20 includes a disposition region 23 positioned in a center part in plan view and a corner region 24 positioned in a corner part in each of the four corners in plan view. The shape of each of the disposition region 23 and the corner region 24 is, for example, a rectangular shape in plan view, and more preferably, a square shape in plan view, but is not limited to such a shape. In this embodiment, the area of the substrate 20 in plan view (that is, the total area of the disposition region 23 and the four corner regions 24) is smaller than the area of the semiconductor element 10, but is not limited to this example.

Along the perimeter of the disposition region 23, a plurality of wall-shaped barrier parts (a plurality of walls) 21 and a plurality of non-barrier regions (a plurality of non-wall regions) 22 in each of which the barrier part (wall) 21 is not provided are formed. Each barrier part 21 in this embodiment is a bent portion of the substrate 20. In an example, the barrier part 21 is provided on each of the four sides of the disposition region 23 in plan view and has a rectangular wall surface standing in the vertical direction. The barrier parts 21 provided on the respective four sides are preferably have the same height. The height H1 of the barrier parts 21 may be 0.17 times the thickness H2 of the substrate 20 or more.

The non-barrier region (non-wall region) 22 is positioned in the corner part in each of the four corners of a rectangle that defines the disposition region 23. In an example, each non-barrier region 22 is formed between a corresponding one of the barrier parts 21 provided on the respective four sides of the disposition region 23 and another corresponding one of the barrier parts 21. Note that the non-barrier regions 22 are preferably positioned symmetrically about the center of the disposition region 23 in plan view.

In the disposition region 23, the mounting material 30 is disposed. The mounting material 30 is disposed on the disposition region 23, and a space formed among the barrier parts 21 of the substrate 20 and the semiconductor element 10 is filled with the mounting material 30. The material of the mounting material 30 is, for example, Ag, paste, or solder. A portion of the mounting material 30 leaks outside the disposition region 23 through the non-barrier region 22 and is solidified on the corner region 24 as a leaking portion 31.

FIG. 2 is a cross-sectional view of the semiconductor device 100. As shown in FIG. 2, the mounting material 30 is interposed between an upper end 21a of the barrier part 21 and the semiconductor element 10. On the outer side of the upper end 21a of the barrier part 21, the leaking portion 31 of the mounting material 30 leaking outside the disposition region 23 is solidified.

### 1.2. Method for Manufacturing Semiconductor Device 100

The process of manufacturing the semiconductor device 100 according to this embodiment will be described below. As shown in FIG. 3, the process of manufacturing the semiconductor device 100 includes a substrate processing process (S100), a mounting material disposition process (S200), and a semiconductor element disposition process (S300).

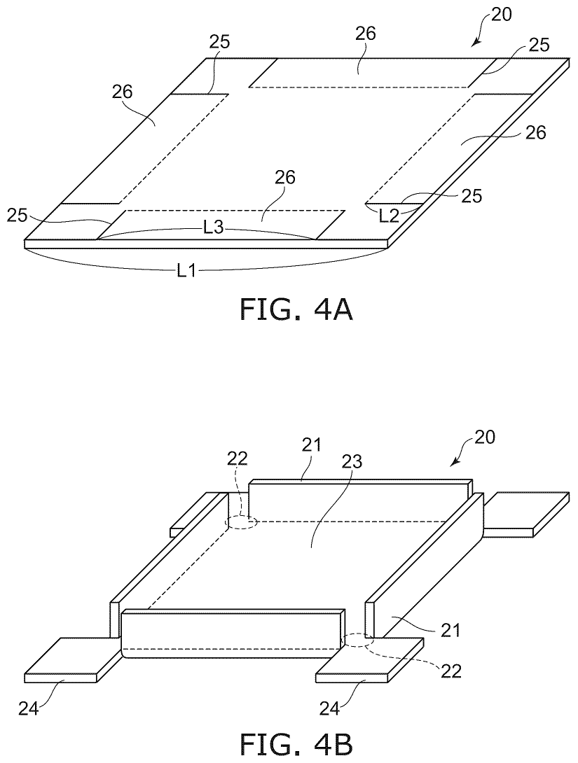

In the substrate processing process in step S100, portions of the substrate 20 are bent to form, around the disposition region 23 in which the mounting material 30 is to be disposed, the wall-shaped barrier parts 21 and the non-barrier regions 22 in each of which the barrier part 21 is not provided. Specifically, as shown in FIG. 4A, first, for each side of the four sides of the substrate 20 in plan view, a pair of cuts 25 orthogonal to the side of the substrate 20 are made. Although the length of the cuts 25 can be set as appropriate, for example, the length L2 of the cuts 25 relative to the length L1 of the sides of the substrate 20 may satisfy 0.1≥L2/L1 ≥0.01. Further, the length L3 between the pair of cuts 25 on one side of the substrate 20 may satisfy 0.9≥ L3/L1 ≥0.7.

Next, a rectangular region 26 sandwiched between the pair of cuts 25 made for each side of the substrate 20 is raised in the vertical direction. Accordingly, the barrier parts 21 raised in the vertical direction are formed as shown in FIG. 4B. Each non-barrier region 22 is formed between a corresponding one of the barrier parts 21 and another corresponding one of the barrier parts 21. Further, the corner region 24 is formed outside each non-barrier region 22 in plan view.

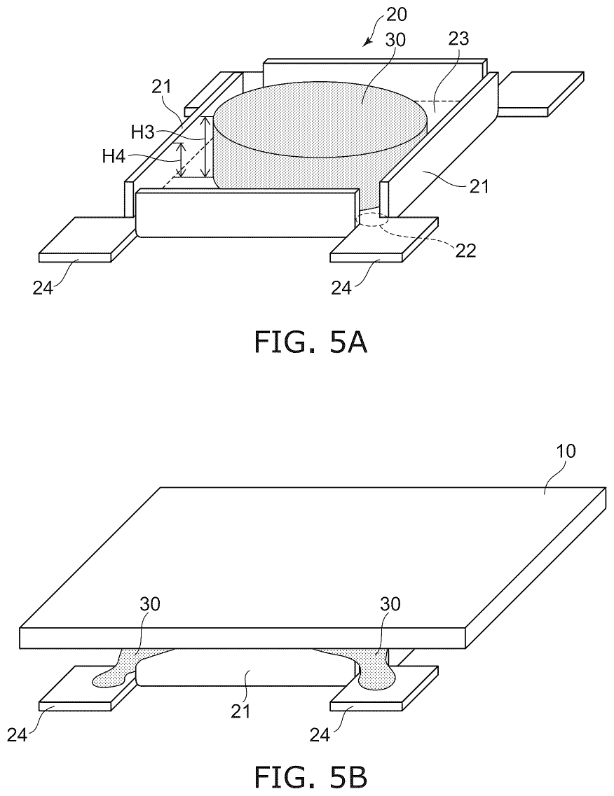

In the mounting material disposition process in step S200, the mounting material 30 is disposed in the disposition region 23 of the substrate 20 as shown in FIG. 5A. Although the mounting material 30 is disposed in a cylindrical form in the example shown in FIG. 5A, FIG. 5A is only a schematic diagram and this example is not restrictive. For example, the mounting material 30 may be disposed in a conical form or may be disposed in other forms. In plan view, the area of the mounting material 30 is preferably about 100% of the area of the disposition region 23. Further, the height H3 of the mounting material 30 is higher than the height H4 of the inner wall surface of each barrier part 21 and may satisfy, for example, H3/H4 ≥1.1.

In the semiconductor element disposition process in step S300, the semiconductor element 10 is disposed on the mounting material 30 as shown in FIG. 5B. When the semiconductor element 10 is disposed on the mounting material 30, the mounting material 30 is pressed and extended by the load of the semiconductor element 10. As a result, a portion of the mounting material 30 leaks through each non-barrier region 22 to the corner region 24 outside the non-barrier region 22 in plan view, and is solidified thereafter. Accordingly, the semiconductor device 100 is manufactured.

### 1.3. Summation

According to the embodiment described above, the semiconductor device 100 includes the substrate 20, the mounting material 30 disposed on the substrate 20, and the semiconductor element 10 disposed on the mounting material 30. The wall-shaped barrier part 21 and the non-barrier region 22 in which the barrier part 21 is not provided are formed along the perimeter of the mounting material 30 on the substrate 20. This facilitates stable application of the mounting material.

That is, even when the amount of the mounting material is large relative to the space formed among the disposition region 23 of the substrate 20, the barrier part 21, and the semiconductor element 10, the mounting material 30 pressed and extended by the load of the semiconductor element 10 leaks to the corner region 24 through the non-barrier region 22 and is solidified in the semiconductor element disposition process (S300), and therefore, the impact on manufacturing the semiconductor device 100 can be reduced. This removes the need to precisely adjust the amount of the mounting material and facilitates stable application of the mounting material.

In plan view, the barrier part 21 is provided on each of the four sides of a predetermined rectangle, and the non-barrier region 22 is positioned in the corner part in each of the four corners of the rectangle. This allows a portion of the mounting material, with which a region surrounded by the barrier part 21 provided on each of the four sides of the rectangle is filled, to flow out through the non-barrier region provided in each of the four corners of the rectangle with certainty, and therefore, facilitates stable application of the mounting material.

Further, in plan view, a portion of the mounting material 30 may leak outside through the non-barrier region 22 and may be solidified. This can prevent a reduction in quality of the semiconductor device 100 caused by the applied mounting material 30 climbing the side surface of the semiconductor element 10 and reaching the upper surface of the semiconductor element 10.

Further, the mounting material may be interposed between the upper end 21a of the barrier part 21 and the semiconductor element 10. This removes the need to precisely adjust the amount of the mounting material 30 to be applied and facilitates production of the semiconductor device 100.

Further, the barrier part 21 may be a bent portion of the substrate 20. This allows the barrier part 21 to be provided by using the substrate 20 as one component, and therefore, can reduce the number of components upon production of the semiconductor device 100.

Further, in plan view, the area of the substrate 20 is smaller than the area of the semiconductor element 10. This can reduce the size of the semiconductor device 100 to enable high-density mounting.

In plan view, the plurality of non-barrier regions 22 are preferably positioned symmetrically about the center of the disposition region 23. This allows the mounting material leaking from the disposition region 23 to easily leak uniformly through each of the plurality of non-barrier regions 22, and can further reduce the impact of leaking of the mounting material 30, on the semiconductor device 100.

### 1.4. Modification

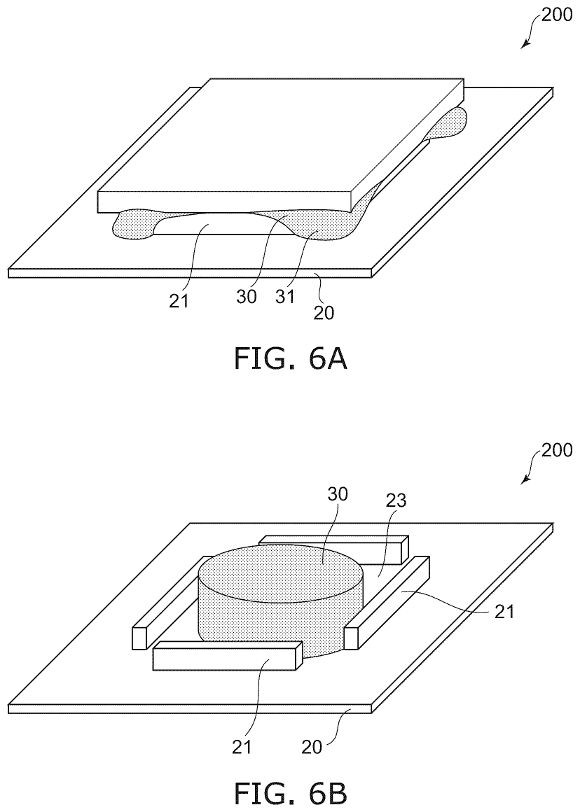

A semiconductor device 200 according to a modification of this embodiment will be described with reference to FIG. 6A and FIG. 6B with an emphasis on differences from the above-described embodiment. The barrier part 21 included in the semiconductor device 200 according to the modification is different from that in the above-described embodiment in that the barrier part 21 is a member fixed on the substrate 20.

As shown in FIG. 6B, in the modification, the barrier part 21 is fixed on each of the four sides of the disposition region 23 in a center part of the rectangular substrate 20 in plan view. The barrier parts 21 are members separate from the substrate 20 and may be made of a material, such as metal, plastic, rubber, or ceramic. Even with such a configuration, effects similar to those in the above-described embodiment can be obtained.

### 2. OTHER EMBODIMENTS

Although an embodiment of the disclosure has been described above, the disclosure is not limited to the above. For example, although the mounting material 30 is interposed between the semiconductor element 10 and the upper end 21a of the barrier part 21 provided on the substrate 20 in the above-described embodiment, the disclosure is not limited to this form. That is, the semiconductor element 10 may be in contact with the upper end 21a of the barrier part 21.

Further, although the barrier part 21 is provided on each of the four sides of a predetermined rectangle in plan view in the above-described embodiment, the disclosure is not limited to this form. For example, the barrier part 21 may be provided on each of the sides of a predetermined polygon other than a rectangle in plan view. In this case, the non-barrier region 22 may be provided in each of one or more of the corner parts of the predetermined polygon. Alternatively, the barrier part 21 may be provided on the perimeter of a predetermined circle in plan view. In this case, one or more non-barrier regions 22 may be provided on a portion of the perimeter of the predetermined circle.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The invention includes the following forms.

### APPENDIX 1

A semiconductor device including:
a substrate;
a mounting material disposed on the substrate; and
a semiconductor chip disposed on the mounting material, a wall and a non-barrier region in which the wall is not provided being formed along a perimeter of the mounting material on the substrate.

### APPENDIX 2

The device according to appendix 1, in which
the wall is provided on each of four sides of a predetermined rectangle in plan view, and
the non-barrier region is positioned in a corner part in each of four corners of the rectangle.

### APPENDIX 3

The device according to appendix 2, in which a portion of the mounting material leaks outside through the non-barrier region and is solidified in plan view.

### APPENDIX 4

The device according to appendix 1, in which an upper end of the wall is in contact with the semiconductor element.

### APPENDIX 5

The device according to appendix 1, in which the mounting material is interposed between an upper end of the wall and the semiconductor element.

### APPENDIX 6

The device according to appendix 1, in which the wall is a bent portion of the substrate.

### APPENDIX 7

The device according to appendix 1, in which the wall is a member fixed on the substrate.

### APPENDIX 8

The device according to appendix 1, in which an area of the substrate is smaller than an area of the semiconductor element in plan view.

### APPENDIX 9

A method for manufacturing a semiconductor device including a mounting material disposed on a substrate and a semiconductor element disposed on the mounting material, the method including:
bending a portion of the substrate and forming, around a disposition region in which the mounting material is to be disposed, a wall and a non-barrier region in which the wall is not provided;
disposing the mounting material in the disposition region; and
disposing the semiconductor element on the mounting material.

### APPENDIX 10

The method according to appendix 9, in which disposing the semiconductor chip includes disposing the semiconductor element on the mounting material, pressing and extending the mounting material by a load of the semiconductor element, and making a portion of the mounting material leak outside through the non-barrier region in plan view.

What is claimed is:

1. A semiconductor device comprising:
a substrate;
a mounting material disposed on the substrate; and
a semiconductor chip disposed on the mounting material,
a wall and a non-wall region in which the wall is not provided being formed along a perimeter of the mounting material on the substrate.

2. The device according to claim 1, wherein
the wall is provided on each of four sides of a predetermined rectangle in plan view, and
the non-wall region is positioned in each of four corners of the rectangle.

3. The device according to claim 2, wherein a portion of the mounting material leaks outside through the non-wall region and is solidified in plan view.

4. The device according to claim 1, wherein an upper end of the wall is in contact with the semiconductor element.

5. The device according to claim 1, wherein the mounting material is interposed between an upper end of the wall and the semiconductor element.

6. The device according to claim 1, wherein the wall is a bent portion of the substrate.

7. The device according to claim 1, wherein the wall is a member fixed on the substrate.

8. The device according to claim 1, wherein an area of the substrate is smaller than an area of the semiconductor element in plan view.

9. A method for manufacturing a semiconductor device including a mounting material disposed on a substrate and a semiconductor element disposed on the mounting material, the method comprising:
bending a portion of the substrate and forming, around a disposition region in which the mounting material is to be disposed, a wall and a non-wall region in which the wall is not provided;
disposing the mounting material in the disposition region; and
disposing the semiconductor element on the mounting material.

10. The method according to claim 9, wherein disposing the semiconductor element includes disposing the semiconductor element on the mounting material, pressing and extending the mounting material by a load of the semiconductor element, and making a portion of the mounting material leak outside through the non-wall region in plan view.
